(19) United States
(12) Patent Application Publication
(10) Pub. No.: US 2024/0065002 A1
(43) Pub. Date: Feb. 22, 2024

(54) SEMICONDUCTOR DEVICE AND SEMICONDUCTOR PACKAGE COMPRISING THE SAME

(71) Applicant: Samsung Electronics Co., Ltd., Suwon-si (KR)

(72) Inventors: Dongkyu Kim, Suwon-si (KR); Joonsung Kim, Suwon-si (KR); Inhyung Song, Suwon-si (KR); Yeonho Jang, Suwon-si (KR)

(21) Appl. No.: 18/231,341

(22) Filed: Aug. 8, 2023

(30) Foreign Application Priority Data
Aug. 16, 2022 (KR) 10-2022-0102226

(51) Int. Cl. H10B 80/00; H01L 25/18; H01L 23/00; H01L 25/00

(52) U.S. Cl. CPC H10B 80/00; H01L 25/18; H01L 24/20; H01L 25/50; H01L 2224/0557; H01L 2224/06181; H01L 2224/19; H01L 2224/96; H01L 2224/214; H01L 2924/0105; H01L 2924/01049; H01L 2924/01083; H01L 2924/01051; H01L 2924/01029; H01L 2924/01047; H01L 2924/0103; H01L 2924/01082; H01L 24/32; H01L 2224/32145; H01L 24/33; H01L 2224/33181; H01L 24/73; H01L 2224/73204; H01L 2224/73253; H01L 2224/17181; H01L 24/16; H01L 24/17; H01L 24/05; H01L 24/06; H01L 24/19; H01L 24/96; H01L 2224/16145

(57) ABSTRACT

A semiconductor device including a first lower buffer chip, an upper buffer chip disposed on an upper surface of the first lower buffer chip, a plurality of conductive posts spaced apart from the first lower buffer chip and disposed on a lower surface of the upper buffer chip, and a first memory chip stack structure disposed on the upper buffer chip and including a plurality of first memory chips.

### CROSS-REFERENCE TO RELATED APPLICATION

This application is based on and claims priority under 35 U.S.C. § 119 to Korean Patent Application No. 10-2022-0102226, filed on Aug. 16, 2022, in the Korean Intellectual Property Office, the disclosure of which is incorporated by reference herein in its entirety.

### BACKGROUND

Aspects of the inventive concept relate to a semiconductor device and a semiconductor package including the same. More specifically, aspects of the inventive concept relate to a semiconductor device including stacked semiconductor chips and a semiconductor package including the same.

As electronic products are required to be miniaturized, multifunctional, and have high performance, high integration and high speed of semiconductor packages are also required. For this purpose, a semiconductor package having a semiconductor device including stacked semiconductor chips has been developed.

### SUMMARY

Aspects of the inventive concept provide a semiconductor device capable of preventing a load on stacked semiconductor chips and having a high degree of design freedom, and a semiconductor package including the same.

According to an aspect of the inventive concept, there is provided a semiconductor device including a first lower buffer chip, an upper buffer chip disposed on an upper surface of the first lower buffer chip, a plurality of conductive posts spaced apart from the first lower buffer chip and disposed on a lower surface of the upper buffer chip, and a first memory chip stack structure disposed on the upper buffer chip and including a plurality of first memory chips.

According to another aspect of the inventive concept, there is provided a semiconductor package including a redistribution structure, a semiconductor device disposed on the redistribution structure, and a semiconductor chip disposed on the redistribution structure and spaced apart from the semiconductor device in a horizontal direction, wherein the semiconductor device includes a lower buffer chip disposed on the redistribution structure, an upper buffer chip disposed on an upper surface of the lower buffer chip, a plurality of conductive posts spaced apart from the lower buffer chip and disposed on a lower surface of the upper buffer chip, and a memory chip stack structure disposed on the upper buffer chip and including a plurality of memory chips.

According to another aspect of the inventive concept, there is provided a semiconductor device including a lower buffer chip including a first through electrode, a plurality of conductive posts spaced apart from the lower buffer chip and disposed along a periphery of the lower buffer chip, a first redistribution structure disposed on the lower buffer chip and the plurality of conductive posts, an upper buffer chip disposed on the first redistribution structure and including a second through electrode, and a memory chip stack structure disposed on the upper buffer chip and including a plurality of memory chips, wherein a horizontal area of the upper buffer chip is greater than a horizontal area of the lower buffer chip and a vertical length of the upper buffer chip is greater than a vertical length of the lower buffer chip, wherein a width of the plurality of conductive posts is greater than a width of the first through electrode and a width of the second through electrode.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view showing a semiconductor device according to an embodiment of the inventive concept;

FIGS. 2A and 2B are layout diagrams illustrating a semiconductor device according to an embodiment of the inventive concept;

FIG. 3 is a cross-sectional view illustrating a semiconductor device according to an embodiment of the inventive concept;

FIG. 4 is a cross-sectional view illustrating a semiconductor device according to an embodiment of the inventive concept;

FIG. 5 is a cross-sectional view illustrating a semiconductor device according to an embodiment of the inventive concept;

FIG. 6 is a cross-sectional view illustrating a semiconductor package according to an embodiment of the inventive concept; and

FIGS. 7A to 7G are cross-sectional views illustrating respective steps of a semiconductor device manufacturing process according to an embodiment of the inventive concept.

### DETAILED DESCRIPTION OF THE EMBODIMENTS

Hereinafter, embodiments of the technical idea of the inventive concept will be described in detail with reference to the accompanying drawings. The same reference numerals are used for the same components in the drawings, and duplicate descriptions thereof are omitted.

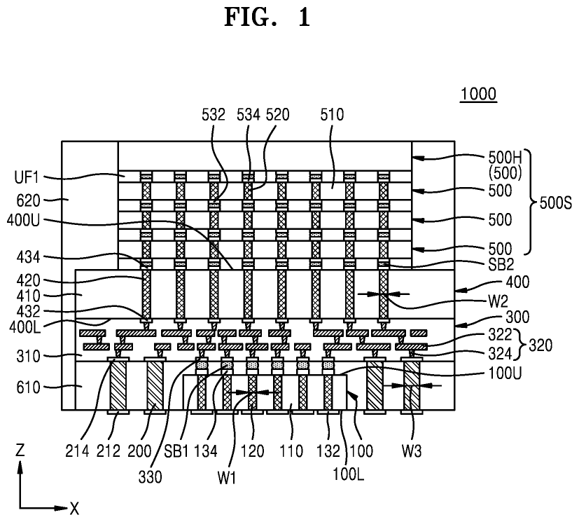

FIG. 1 is a cross-sectional view showing a semiconductor device according to an embodiment of the inventive concept.

Referring to FIG. 1, a semiconductor device 1000 includes a lower buffer chip 100, a plurality of conductive posts 200, a first redistribution structure 300, an upper buffer chip 400, and a memory chip stack structure 500S.

Hereinafter, unless otherwise defined, a direction perpendicular to an upper surface 100U of the lower buffer chip 100 is defined as a Z direction, and directions parallel to the upper surface 100U of the lower buffer chip 100 are defined as the X direction and the Y direction. The X direction, the Y direction, and the Z direction may be perpendicular to each other.

The lower buffer chip 100 may include a first semiconductor substrate 110, a plurality of first through electrodes 120, a plurality of first lower pads 132, and a plurality of first upper pads 134.

In an embodiment, the lower buffer chip 100 may be a buffer chip including a serial-parallel conversion circuit. In an embodiment, the lower buffer chip 100 may be a buffer chip for controlling a high bandwidth memory (HBM) dynamic random access memory (DRAM) semiconductor chip.

In an embodiment, the lower buffer chip 100 may include an arithmetic circuit configured to process data stored in a plurality of memory chips 500. In addition, since the plurality of memory chips 500 include only a memory cell and do not separately include an arithmetic circuit, a thermal load and an electrical load that may be applied to the plurality of memory chips 500 may be reduced.

The first semiconductor substrate 110 may include a group IV semiconductor, such as silicon (Si) or germanium (Ge), a group IV-IV compound semiconductor, such as silicon-germanium (SiGe) or silicon carbide (SiC), or a group III-V compound semiconductor, such as gallium arsenide (GaAs), indium arsenide (InAs), or indium phosphorus (InP). The first semiconductor substrate 110 may include a conductive region, for example, a well doped with an impurity or a structure doped with an impurity. The first semiconductor substrate 110 may have various device isolation structures, such as a shallow trench isolation (STI) structure.

The first semiconductor substrate 110 may have an active surface and an inactive surface opposite to the active surface. A plurality of individual devices of various types may be formed on the active surface of the first semiconductor substrate 110. The plurality of the individual devices may include, for example, metal-oxide-semiconductor field effect transistors (MOSFETs), such as complementary metal-oxide-semiconductor (CMOS) transistors, system large scale integration (LSI), image sensors, such as CMOS imaging sensors (CISs), micro-electro-mechanical systems (MEMS), active devices, passive devices, and the like.

The first through electrode 120 penetrates the first semiconductor substrate 110 and may extend in a direction (Z direction) perpendicular to the upper surface 100U of the lower buffer chip 100. The first through electrode 120 may electrically connect the first upper pad 134 to the first lower pad 132.

The first lower pad 132 may be disposed on a lower surface 100L of the lower buffer chip 100. The first lower pad 132 may be disposed to overlap the first through electrode 120 in the vertical direction (Z direction). The first lower pad 132 may be connected to the first through electrode 120.

The first upper pad 134 may be disposed on the upper surface 100U of the lower buffer chip 100. The first upper pad 134 may be disposed to overlap the first through electrode 120 and the first lower pad 132 in the vertical direction (Z direction). Side surfaces of the first upper pad 134 may be surrounded by a first molding layer 610.

A first connection terminal SB1 may be disposed on the first upper pad 134. The first connection terminal SB1 may be, for example, a solder ball or a solder bump. The first connection terminal SB1 may include a solder material. The solder material may be, for example, tin (Sn), indium (In), bismuth (Bi), antimony (Sb), copper (Cu), silver (Ag), zinc (Zn), lead (Pb), and/or or an alloy thereof. The lower buffer chip 100 and the first redistribution structure 300 may be electrically connected to each other through the first connection terminal SB1.

The plurality of conductive posts 200 may be spaced apart from the lower buffer chip 100 and disposed on a lower surface 400L of the upper buffer chip 400. For example, the first redistribution structure 300 may be disposed between the lower surface 400L of the upper buffer chip 400 and the plurality of conductive posts 200. A plurality of post lower pads 212 may be respectively disposed on lower surfaces of the plurality of conductive posts 200, and a plurality of post upper pads 214 may be respectively disposed on upper surfaces of the plurality of conductive posts 200. The plurality of post lower pads 212 and the plurality of post upper pads 214 respectively corresponding thereto may overlap in the vertical direction (Z direction). The widths of the plurality of post lower pads 212 and the plurality of post upper pads 214 may be greater than the width W3 of the plurality of conductive posts 200, but aspects of the inventive concept are not limited thereto. The plurality of conductive posts 200 may be electrically connected to the first redistribution structure 300 through the plurality of post upper pads 214, respectively.

In example embodiments, the width W3 of the conductive post 200 may be greater than the width W1 of the first through electrode 120 and the width W2 of the second through electrode 420. Accordingly, power may be easily supplied to the upper buffer chip 400 and the memory chip stack structure 500S through the plurality of conductive posts 200.

In an embodiment, the conductive posts 200 may include copper (Cu) but aspects of the inventive concept are not limited thereto.

In an embodiment, the semiconductor device 1000 may further include the first molding layer 610. The first molding layer 610 may surround the lower buffer chip 100 and the plurality of conductive posts 200. Specifically, the first molding layer 610 may surround side surfaces of the lower buffer chip 100, a portion of the upper surface 100U of the lower buffer chip 100 in which the first upper pad 134 is not disposed, and sidewalls of the conductive posts 200.

In example embodiments, the first molding layer 610 may be formed of an epoxy-based material, a thermosetting material, a thermoplastic material, or the like. For example, the first molding layer 610 may be formed of an epoxy molding compound (EMC). In other embodiments, the first molding layer 610 may include Ajinomoto Build-up Film (ABF), FR-4, Bismaleimide Triazine (BT), EMC, or the like.

The first redistribution structure 300 may be disposed on the upper surface 100U of the lower buffer chip 100. In an embodiment, the first redistribution structure 300 may be electrically connected to the lower buffer chip 100, the conductive posts 200, and the upper buffer chip 400. Specifically, the first redistribution structure 300 may be configured to electrically connect the lower buffer chip 100 and the conductive posts 200 to the upper buffer chip 400.

The first redistribution structure 300 may include a first redistribution insulating layer 310, a plurality of first redistribution patterns 320. In accordance with aspects of the inventive concept, the first redistribution structure may also include a plurality of first redistribution pads 330.

The first redistribution insulating layer 310 may surround the plurality of first redistribution patterns 320. The first redistribution insulating layer 310 may be formed of, for example, a photo imageable dielectric (PID), photosensitive polyimide (PSPI), silicon oxide, or silicon nitride.

The plurality of first redistribution patterns 320 may include a plurality of first redistribution line patterns 322 and a plurality of first redistribution vias 324. A portion of the plurality of first redistribution vias 324 may pass through at least a portion of the first redistribution insulating layer 310. Some of the plurality of first redistribution vias 324 and a portion of the plurality of first redistribution line patterns 322 may be connected to each other in a vertical direction (Z direction). A portion of the plurality of first redistribution vias 324 may be connected to the second lower pad 432, another portion of the plurality of first redistribution vias 324 may be connected to the post upper pad 214, and another portion of the plurality of first redistribution vias 324 may be connected to the plurality of the first connection terminals SB1. In accordance with aspects of the inventive concept, the respective portion of the plurality of first redistribution vias 324 may be connected to the plurality of the first connection terminals SB1 via the plurality of first redistribution pads 330. In an embodiment, some of the plurality of first redistribution line patterns 322 and some of the plurality of first redistribution vias 324 may be formed through a dual damascene process. For example, the uppermost ones of the first redistribution vias 324 and the uppermost ones of the first redistribution line patterns 322 may be simultaneously formed through a dual damascene process. In this case, the uppermost ones of the first redistribution vias 324 and the uppermost ones of the first redistribution line patterns 322 may be integrally formed.

In an embodiment, the first redistribution via 324 may have a tapered shape in which a horizontal width thereof increases away from the lower buffer chip 100.

In an embodiment, unlike shown in FIG. 1, the first redistribution pad 330 may be disposed at a position corresponding to the second upper pad 432 or a position corresponding to the post upper pad 214. In this case, the first redistribution pad 330 and the second upper pad 432 corresponding thereto may be directly connected to each other or connected through a connection terminal (not shown), and the first redistribution pad 330 and the post upper pad 214 corresponding thereto may also be directly connected to each other or may be connected through a connection terminal (not shown).

In an embodiment, the first redistribution pattern 320 and the first redistribution pad 330 may be formed of copper (Cu), titanium (Ti), titanium tungsten (TiW), titanium nitride (TiN), tantalum (Ta), tantalum. Nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof.

The upper buffer chip 400 may be disposed on the first redistribution structure 300. The upper buffer chip 400 may include a second semiconductor substrate 410, a second through electrode 420, a second lower pad 432, and a second upper pad 434. Each component of the upper buffer chip 400 may be similar to each component of the lower buffer chip 100 corresponding thereto.

In an embodiment, the upper buffer chip 400 may be a buffer chip including a serial-parallel conversion circuit. In an embodiment, the upper buffer chip 400 may be a buffer chip for controlling the HBM DRAM semiconductor chip.

In an embodiment, the upper buffer chip 400 may include an arithmetic circuit configured to calculate data stored in the plurality of memory chips 500. The upper buffer chip 400 includes the arithmetic circuit, and some operations may be performed by the semiconductor device 1000.

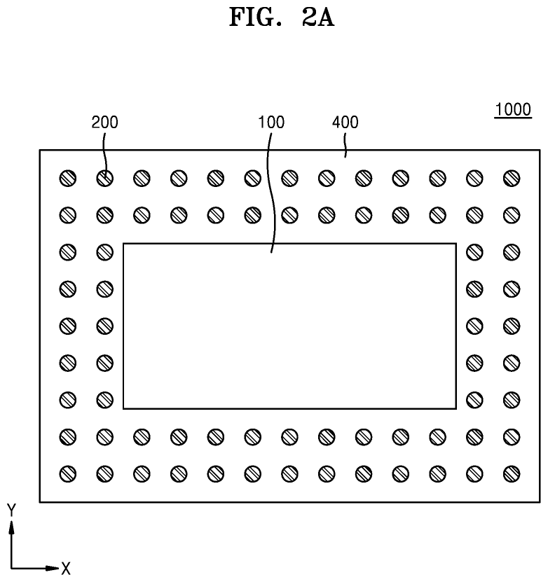

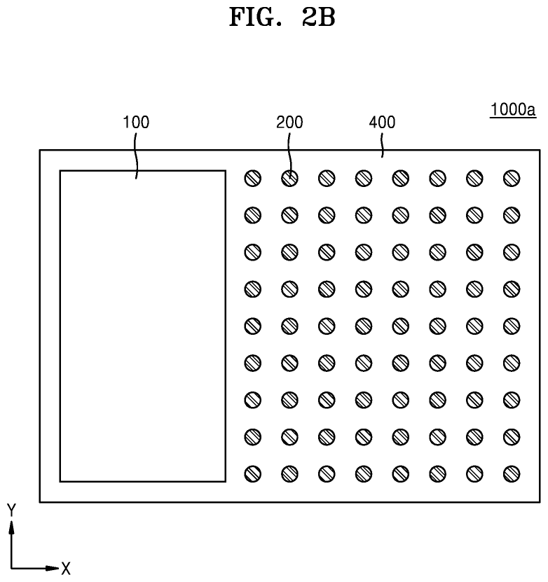

In an embodiment, referring to FIGS. 1 and 2A together, the horizontal area of the upper buffer chip 400 may be larger than the horizontal area of the lower buffer chip 100. Here, the horizontal area means an area on a plane perpendicular to the vertical direction (Z direction). Accordingly, the upper buffer chip 400 and the lower buffer chip 100 may overlap in the vertical direction (Z direction). In an embodiment, the vertical length (Z-direction length) of the upper buffer chip 400 may be greater than the vertical length (Z-direction length) of the lower buffer chip 100.

The second semiconductor substrate 410 may be disposed on the first redistribution structure 300. The second through electrode 420 passes through the second semiconductor substrate 410 and may extend in a vertical direction (Z direction). The second through electrode 420 may electrically connect the second upper pad 434 to the second lower pad 432.

The second lower pad 432 may be disposed on the lower surface 400L of the upper buffer chip 400. Both sidewalls of the second lower pad 432 may be surrounded by the first redistribution insulating layer 310. The second lower pad 432 may be connected to the first redistribution via 324.

The second upper pad 434 may be disposed on the upper surface 400U of the upper buffer chip 400. Both sidewalls of the second upper pad 434 may be surrounded by a first underfill layer UF1.

A second connection terminal SB2 may be disposed on the second upper pad 434. The second connection terminal SB2 may be similar to the first connection terminal SB1. The upper buffer chip 400 and the memory chip stack structure 500S may be electrically connected to each other through the second connection terminal SB2.

The memory chip stack structure 500S may be disposed on the upper buffer chip 400. The memory chip stack structure 500S may include a plurality of memory chips 500 sequentially stacked. Each of the stacked plurality of memory chips 500 may have substantially the same width in a horizontal direction. Among the plurality of memory chips 500, an uppermost memory chip 500H may have a greater thickness in the vertical direction (Z direction) than the other memory chips 500.

In an embodiment, the plurality of memory chips 500 may be, for example, a volatile memory semiconductor chip, such as dynamic random access memory (DRAM) or static random access memory (SRAM), or may be a non-volatile memory chip, such as phase-change random access memory (PRAM), magnetoresistive random access memory (MRAM), ferroelectric random access memory (FeRAM), or resistive random access memory (ReRAM). In an embodiment, each of the plurality of memory chips 500 may be a DRAM chip, and the memory chip stack structure 500S may constitute an HBM.

In FIG. 1, the memory chip stack structure 500S is illustrated as including four memory chips 500, but is not limited thereto. In an embodiment, the memory chip stack structure 500S may include multiples of 4, for example, 8, 12, or 16 memory chips 500.

The plurality of memory chips 500 may include a third semiconductor substrate 510, a third through electrode 520, a third lower pad 532, and a third upper pad 534. Each component of the plurality of memory chips 500 may be similar to each component of the lower buffer chip 100 corresponding thereto.

The third semiconductor substrate 510 may be disposed on the upper buffer chip 400. The third through electrode 520 passes through the third semiconductor substrate 510 and may extend in a vertical direction (Z direction). The third through electrode 520 may electrically connect the third upper pad 534 to the third lower pad 532.

The third lower pad 532 may be disposed on lower surfaces of the plurality of memory chips 500. A third lower pad 532 of each of the plurality of memory chips 500 may be electrically connected to a third upper pad 534 of an underlying memory chip 500 through a second connection terminal SB2. Meanwhile, the third lower pad 532 of the lowermost one among the plurality of memory chips 500 may be electrically connected to the second upper pad 434 through the second connection terminal SB2.

The third upper pad 534 may be disposed on upper surfaces of the plurality of memory chips 500. The third upper pad 534 of each of the plurality of memory chips 500 may be electrically connected to the third lower pad 532 of the overlying memory chip 500 through the second connection terminal SB2.

In an embodiment, the uppermost memory chip 500H among the plurality of memory chips 500 may not include the third through electrode 520 and the third upper pad 534.

The first underfill layer UF1 may be disposed between the plurality of memory chips 500. The first underfill layer UF1 may surround the third lower pad 532, the third upper pad 534, the second connection terminal SB2, and the second upper pad 434. The first underfill layer UF1 may be, for example, a BPA epoxy resin, a BPF epoxy resin, an aliphatic epoxy resin, or a cycloaliphatic epoxy resin.

In an embodiment, the semiconductor device 1000 may further include a second molding layer 620. The second molding layer 620 may surround the first molding layer 610, the upper buffer chip 400, and the memory chip stack structure 500S. Specifically, the second molding layer 620 may surround side surfaces of the first molding layer 610, a portion of the upper surface 400U of the upper buffer chip 400 where the memory chip stack structure 500S is not disposed, side surfaces of the upper buffer chip 400, and side surfaces of the memory chip stack structure 500S. In this case, the upper surface of the second molding layer 620 may be coplanar with the upper surface of the memory chip stack structure 500S. In an embodiment, unlike shown in FIG. 1, the second molding layer 620 may cover the upper surface of the memory chip stack structure 500S.

In example embodiments, the second molding layer 620 may be formed of an epoxy-based material, a thermosetting material, a thermoplastic material, or the like. For example, the second molding layer 620 may be formed of an EMC. In other embodiments, the second molding layer 620 may include ABF, FR-4, BT, EMC, or the like.

In an embodiment, the second molding layer 620 may include a material that is different from that of the first molding layer 610. For example, the first molding layer 610 may include EMC, and the second molding layer 620 may include ABF.

The semiconductor device 1000 according to an embodiment of the inventive concept includes a lower buffer chip 100 and an upper buffer chip 400 disposed on the lower buffer chip 100. Accordingly, compared to a conventional semiconductor device including one buffer chip, a load applied to the lower and upper buffer chips 100 and 400 may be reduced. In addition, as the lower buffer chip 100 and the upper buffer chip 400 are stacked in the vertical direction (Z direction), more functions may be included in the buffer chips 100 and 400 than in a conventional semiconductor device including one buffer chip, such that through this, the degree of freedom in designing a semiconductor device may be increased.

FIGS. 2A and 2B are layout diagrams illustrating a semiconductor device according to an embodiment of the inventive concept. Specifically, FIG. 2A is a layout diagram illustrating the semiconductor device 1000 illustrated in FIG. 1, and FIG. 2B is a layout diagram illustrating a semiconductor device 1000a according to another embodiment of the inventive concept.

Referring to FIG. 2A, in the semiconductor device 1000, the lower buffer chip 100 may vertically overlap the center of the upper buffer chip 400. In this case, the plurality of conductive posts 200 may be spaced apart from the lower buffer chip 100 and surround the lower buffer chip 100. Specifically, the plurality of conductive posts 200 may be spaced apart from the lower buffer chip 100 and surround all sides of the lower buffer chip 100.

Referring to FIG. 2B, in the semiconductor device 1000a, the lower buffer chip 100 may vertically overlap an edge portion of the upper buffer chip 400. In this case, the plurality of conductive posts 200 may be spaced apart from the lower buffer chip 100 and disposed around only one side of the lower buffer chip 100. Specifically, the plurality of conductive posts 200 may be spaced apart from the lower buffer chip 100, and may be disposed only around the other side of the lower buffer chip 100 opposite to one side of the lower buffer chip 100 corresponding to the edge portion of the upper buffer chip 400 vertically overlapping with the lower buffer chip 100.

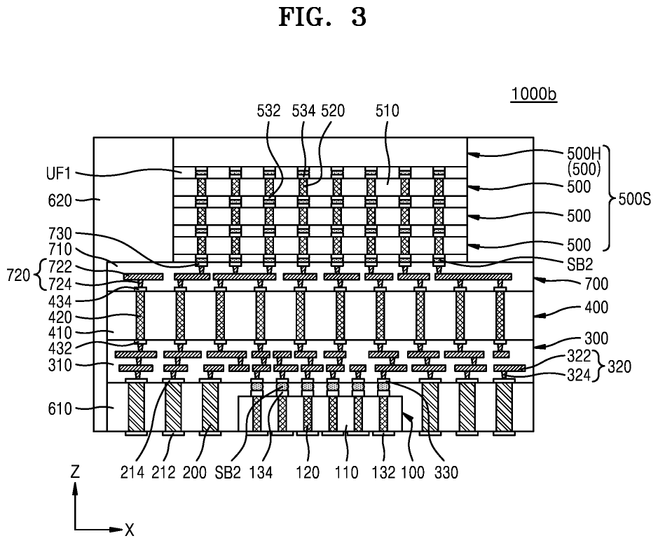

FIG. 3 is a cross-sectional view illustrating a semiconductor device 1000b according to an embodiment of the inventive concept. Since each component of the semiconductor device 1000b shown in FIG. 3 is similar to each component of the semiconductor device 1000 described with reference to FIG. 1, the differences will be mainly described below.

Referring to FIG. 3, the semiconductor device 1000b includes a lower buffer chip 100, a plurality of conductive posts 200, a first redistribution structure 300, an upper buffer chip 400, a memory chip stack structure 500S, and a second redistribution structure 700.

The second redistribution structure 700 may be disposed between the memory chip stack structure 500S and the upper buffer chip 400. The second redistribution structure 700 may electrically connect the memory chip stack structure 500S to the upper buffer chip 400. The second redistribution structure 700 may be similar to the first redistribution structure 300 described with reference to FIG. 1.

The second redistribution structure 700 may include a second redistribution insulating layer 710, a plurality of second redistribution patterns 720, and a plurality of second redistribution pads 730.

The second redistribution insulating layer 710 may be disposed on the upper buffer chip 400. The second redistribution insulating layer 710 may surround the plurality of second redistribution patterns 720.

The plurality of second redistribution patterns 720 may include a plurality of second redistribution line patterns 722 and a plurality of second redistribution vias 724. Some of the plurality of second redistribution vias 724 may pass through at least a portion of the second redistribution insulating layer 710. Some of the plurality of second redistribution vias 724 and some of the plurality of second redistribution line patterns 722 may be connected to each other in a vertical direction (Z direction). Some of the plurality of second redistribution vias 724 may be connected to the second upper pad 434, and other ones of the plurality of second redistribution vias 724 may be connected to the second redistribution pad 730.

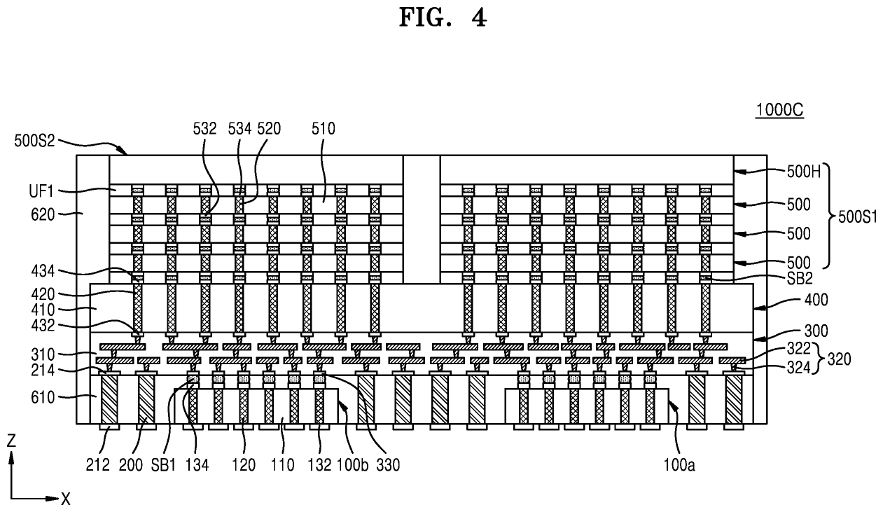

FIG. 4 is a cross-sectional view illustrating a semiconductor device 1000c according to an embodiment of the inventive concept. Since each component of the semiconductor device 1000c shown in FIG. 4 is similar to each component of the semiconductor device 1000 described with reference to FIG. 1, the differences will be mainly described below.

Referring to FIG. 4, the semiconductor device 1000c may include a first lower buffer chip 100a, a second lower buffer chip 100b, a plurality of conductive posts 200, a first redistribution structure 300, an upper buffer chip 400, a first memory chip stack structure 500S1, and a second memory chip stack structure 500S2.

The first lower buffer chip 100a and the second lower buffer chip 100b may be disposed on the lower surface of the upper buffer chip 400. The first lower buffer chip 100a and the second lower buffer chip 100b may be horizontally spaced apart from each other. The first lower buffer chip 100a and the second lower buffer chip 100b may have functions and shapes similar to those of the lower buffer chip 100 described with reference to FIG. 1. In this case, the first lower buffer chip 100a and the second lower buffer chip 100b may be disposed on the lower surface of the upper buffer chip 400 to achieve line symmetry with respect to a virtual center line passing through the center of the upper buffer chip 400.

The plurality of conductive posts 200 may be disposed on the lower surface of the upper buffer chip 400. The plurality of conductive posts 200 may surround the first lower buffer chip 100a and the second lower buffer chip 100b.

The first molding layer 610 may surround the first lower buffer chip 100a, the second lower buffer chip 100b, and the plurality of conductive posts 200. The first molding layer 610 may surround side surfaces of the first lower buffer chip 100a, at least a portion of an upper surface of the first lower buffer chip 100a, side surfaces of the second lower buffer chip 100b, at least a portion of an upper surface of the second lower buffer chip 100b, and sidewalls of the plurality of conductive posts 200.

The first redistribution structure 300 may be disposed on the plurality of conductive posts 200, the first lower buffer chip 100a, and the second lower buffer chip 100b. The first redistribution structure 300 may vertically overlap the plurality of conductive posts 200, the first lower buffer chip 100a, and the second lower buffer chip 100b.

The upper buffer chip 400 may be disposed on the first redistribution structure 300. The upper buffer chip 400 may vertically overlap the plurality of conductive posts 200, the first lower buffer chip 100a, and the second lower buffer chip 100b. In an embodiment, the horizontal area of the upper buffer chip 400 may be larger than each of the horizontal area of the first lower buffer chip 100a and the horizontal area of the second lower buffer chip 100b.

The first memory chip stack structure 500S1 and the second memory chip stack structure 500S2 may be disposed on the upper surface of the upper buffer chip 400. The first memory chip stack structure 500S1 and the second memory chip stack structure 500S2 may be horizontally spaced apart from each other. Each of the first memory chip stack structure 500S1 and the second memory chip stack structure 500S2 may be similar to the memory chip stack structure 500S described with reference to FIG. 1. Each of the first memory chip stack structure 500S1 and the second memory chip stack structure 500S2 may vertically overlap the upper buffer chip 400. In this case, the first memory chip stack structure 500S1 and the second memory chip stack structure 500S2 may achieve line symmetry with respect to a virtual center line passing through the center of the upper buffer chip 400.

The second molding layer 620 may surround the first molding layer 610, the upper buffer chip 400, the first memory chip stack structure 500S1, and the second memory chip stack structure 500S2. Specifically, the second molding layer 620 may surround the side surfaces of the first molding layer 610, the side surfaces of the upper buffer chip 400, a portion of the upper surface of the upper buffer chip 400, the side surfaces of the first memory chip stack structure 500S1, and the side surfaces of the second memory chip stack structure 500S2. The second molding layer 620 may fill a space between the first memory chip stack structure 500S1 and the second memory chip stack structure 500S2.

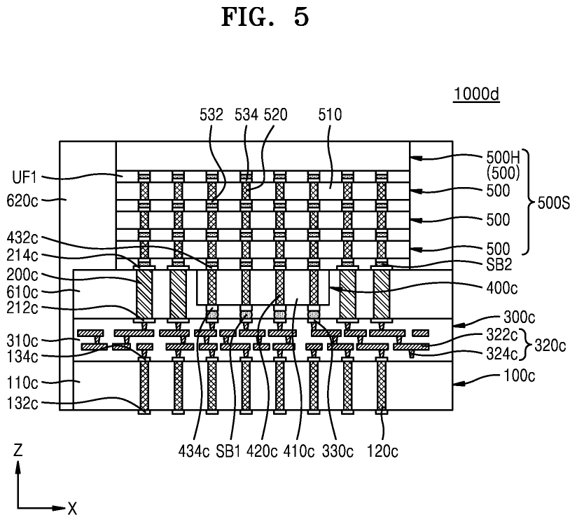

FIG. 5 is a cross-sectional view illustrating a semiconductor device 1000d according to an embodiment of the inventive concept. Since each component of the semiconductor device 1000d shown in FIG. 5 is similar to each component of the semiconductor device 1000 described with reference to FIG. 1, the differences will be mainly described below.

Referring to FIG. 5, the semiconductor device 1000d may include a lower buffer chip 100c, a first redistribution structure 300c, an upper buffer chip 400c, a plurality of conductive posts 200c, and a memory chip stack structure 500S.

The lower buffer chip 100c may include a first semiconductor substrate 110c, a first through electrode 120c, a first lower pad 132c, and a first upper pad 134c. In an embodiment, the horizontal area of the lower buffer chip 100c may be larger than the horizontal area of the upper buffer chip 400c.

The first redistribution structure 300c may be disposed on the lower buffer chip 100c. In this case, the horizontal width of the first redistribution structure 300c may be substantially the same as the horizontal width of the lower buffer chip 100c.

The upper buffer chip 400c may be disposed on the first redistribution structure 300c. The upper buffer chip 400c may include a second semiconductor substrate 410c, a second through electrode 420c, a second lower pad 432c, and a second upper pad 434c. In an embodiment, the vertical length (Z direction length) of the upper buffer chip 400c may be less than the vertical length (Z direction length) of the lower buffer chip 100c.

The plurality of conductive posts 200c may be disposed on the first redistribution structure 300c. The plurality of conductive posts 200c may be spaced apart from the upper buffer chip 400c and surround the upper buffer chip 400c. The plurality of conductive posts 200c may include a post upper pad 214c and a post lower pad 212c. The plurality of conductive posts 200c may be electrically connected to the memory chip stack structure 500S through the post upper pad 214c, and may be electrically connected to the first redistribution structure 300c through the post lower pad 212c.

The memory chip stack structure 500S may be disposed on the plurality of conductive posts 200c and the upper buffer chip 400c. A second connection terminal SB2 may be disposed between the memory chip stack structure 500S and the plurality of conductive posts 200c and between the memory chip stack structure 500S and the upper buffer chip 400c. The memory chip stack structure 500S may be electrically connected to the plurality of conductive posts 200c and the upper buffer chip 400c through the second connection terminal SB2.

The first molding layer 610c may surround the upper buffer chip 400c and the plurality of conductive posts 200c. The second molding layer 620c may surround the memory chip stack structure 500S, the first molding layer 610c, the first redistribution structure 300c, and the lower buffer chip 100c.

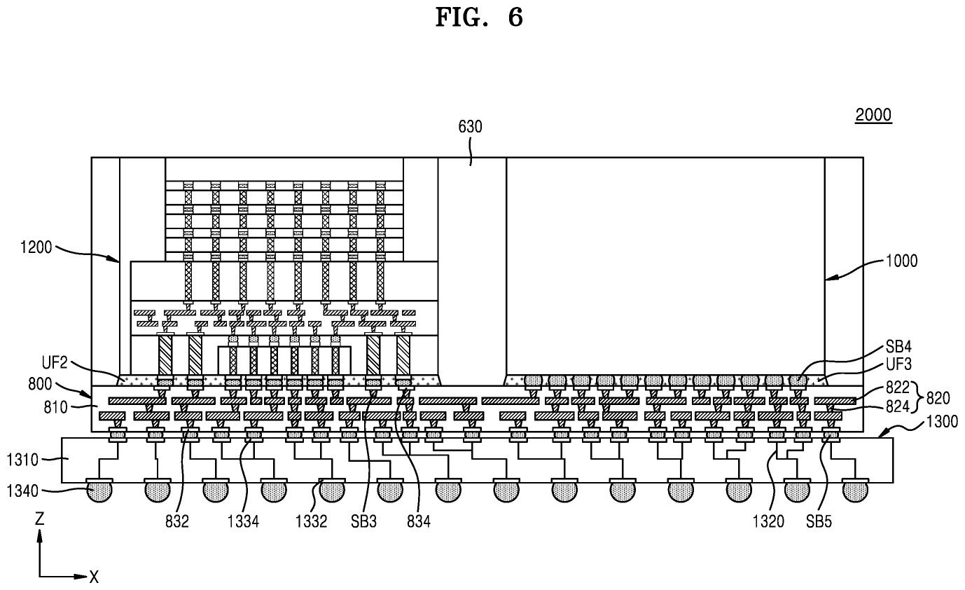

FIG. 6 is a cross-sectional view illustrating a semiconductor package 2000 according to an embodiment of the inventive concept.

Referring to FIG. 6, the semiconductor package 2000 may include a package substrate 1300, a redistribution structure 800 attached on the package substrate 1300, a semiconductor device 1200 disposed on the package substrate 1300, and a semiconductor chip 1000 disposed on the package substrate 1300. Here, the semiconductor device 1200 may be any one of the semiconductor devices 1000, 1000a, 1000b, 1000c, and 1000d described with reference to FIGS. 1 to 5.

In FIG. 6, the semiconductor package 2000 is illustrated as including one semiconductor device 1200 attached on the redistribution structure 800, but is not limited thereto. For example, the semiconductor package 2000 may include one, two, four, eight, or more semiconductor devices 1200. When the semiconductor package 2000 includes a plurality of semiconductor devices 1200, each of the plurality of semiconductor devices 1200 may be a different semiconductor device from another. For example, when the semiconductor package 2000 includes two semiconductor devices, the first semiconductor device may be the semiconductor device 1000 described with reference to FIG. 1, and the second semiconductor device may be the semiconductor device 1000d described with reference to FIG. 5.

The package substrate 1300 may include a base board layer 1310, a plurality of board wiring paths 1320, a plurality of board upper pads 1334, and a plurality of board lower pads 1332. In an embodiment, the package substrate 1300 may be a printed circuit board. For example, the package substrate 1300 may be a multi-layer printed circuit board.

The base board layer 1310 may be made of at least one material selected from phenol resin, epoxy resin, and polyimide. For example, the base board layer 1310 may include, for example, at least one material selected from among Frame Retardant 4 (FR4), Tetrafunctional epoxy, Polyphenylene ether, Epoxy/polyphenylene oxide, Bismaleimide triazine (BT), Thermount, Cyanate ester, Polyimide, and Liquid crystal polymer.

The base board layer 1310 may further include a solder resist layer (not shown) exposing the plurality of board upper pads 1334 and the plurality of board lower pads 1332 on the upper and lower surfaces of the base board layer 1310, respectively. The solder resist layer may be formed of a polyimide film, a polyester film, a flexible solder mask, a photoimageable coverlay (PIC), a photo-imageable solder resist, or the like. The solder resist layer may be formed by, for example, thermosetting a thermosetting ink applied by a silk screen printing method or an inkjet method. The solder resist layer may be formed by, for example, removing a portion of the photosensitive solder resist applied by a screen method or a spray coating method through exposure and development and then thermal curing. The solder resist layer may be formed by, for example, laminating a polyimide film or a polyester film.

The plurality of board wiring paths 1320 may include a plurality of buried conductive layers extending in a horizontal direction and a plurality of conductive vias extending in a vertical direction. The plurality of board wiring paths 1320 may electrically connect the plurality of upper board pads 1334 to the plurality of lower board pads 1332. The plurality of conductive vias may electrically connect the plurality of buried conductive layers located at different vertical levels in the base board layer 1310 to the plurality of upper board pads 1334 and the plurality of lower board pads 1332. The plurality of board wiring paths 1320 may be formed of, for example, electrolytically deposited (ED) copper, rolled-annealed (RA) copper foil, stainless steel foil, aluminum foil, ultra-thin copper foil, sputtered copper, copper alloys, nickel, stainless steel, or beryllium copper.

The plurality of upper board pads 1334 and the plurality of board lower pads 1332 may be respectively disposed on an upper surface and a lower surface of the base board layer 1310. The plurality of upper board pads 1334 may be electrically connected to a redistribution lower pad 832 of the redistribution structure 800 through a fifth connection terminal SB5, and the plurality of board lower pads 1332 may be connected to a plurality of external connection terminals 1340. The fifth connection terminal SB5 may electrically connect the redistribution structure 800 to the package substrate 1300. The plurality of external connection terminals 1340 may connect the semiconductor package 2000 to the outside. The fifth connection terminal SB5 may be similar to the first connection terminal SB1 (refer to FIG. 1).

The redistribution structure 800 may be disposed on the package substrate 1300. The redistribution structure 800 may include a redistribution insulating layer 810, a redistribution pattern 820 including a redistribution line pattern 822 and redistribution vias 824, a redistribution top pad 834, and a redistribution bottom pad 832. The redistribution structure 800 may electrically connect the semiconductor chip 1000 and the semiconductor device 1200 to the package substrate 1300. The redistribution structure 800 may be similar to the first redistribution structure 300 described with reference to FIG. 1.

In an embodiment, the redistribution structure 800 may be an interposer. For example, the redistribution structure 800 may be a redistribution layer (RDL) interposer.

The semiconductor chip 1000 may be disposed on the redistribution structure 800. The semiconductor chip 1000 may be electrically connected to some of the redistribution upper pads 834 of the redistribution structure 800 through the fourth connection terminal SB4. A third underfill layer UF3 is disposed between the semiconductor chip 1000 and the redistribution structure 800, and may surround the fourth connection terminal SB4. The third underfill layer UF3 may be similar to the first underfill layer UF1 described with reference to FIG. 1.

In an embodiment, the semiconductor chip 1000 may be spaced apart from the semiconductor device 1200 in a horizontal direction (e.g., an X direction).

The semiconductor chip 1000 may include, for example, one of a central processing unit (CPU) chip, a graphics processing unit (GPU) chip, an application processor (AP) chip, an application specific integrated circuit (ASIC), or other processing chips.

The semiconductor device 1200 may be disposed on the redistribution structure 800. The semiconductor device 1200 may be electrically connected to the rest of the redistribution upper pads 834 of the redistribution structure 800 through the third connection terminal SB3. The second underfill layer UF2 is disposed on the semiconductor device 1200 and the redistribution structure 800, and may surround the third connection terminal SB3.

The semiconductor package 2000 may further include a third molding layer 630 surrounding the semiconductor chip 1000 and the semiconductor device 1200 on the redistribution structure 800. Specifically, the third molding layer 630 may surround side surfaces of the semiconductor chip 1000 and side surfaces of the semiconductor device 1200. In this case, the upper surface of the third molding layer 630 may be coplanar with the upper surface of the semiconductor chip 1000 and the upper surface of the semiconductor device 1200.

In an embodiment, the third molding layer 630 may cover the upper surface of the semiconductor chip 1000 and the upper surface of the semiconductor device 1200. That is, the upper surface of the third molding layer 630 may be at a higher vertical level than the upper surface of the semiconductor chip 1000 and the upper surface of the semiconductor device 1200.

In example embodiments, the third molding layer 630 may be formed of an epoxy-based material, a thermosetting material, a thermoplastic material, or the like. For example, the third molding layer 630 may be formed of an EMC. In other embodiments, the molding layer 630 may include ABF, FR-4, BT, EMC, or the like.

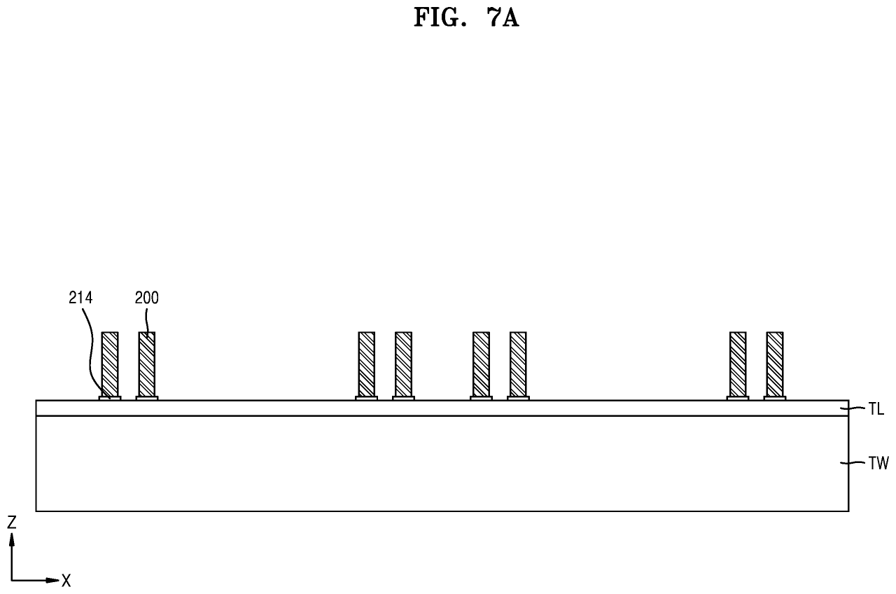

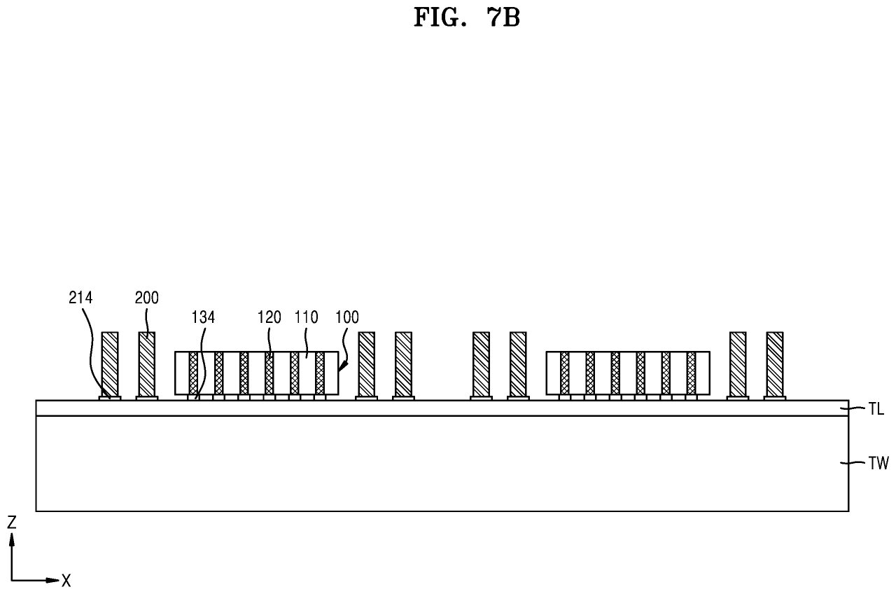

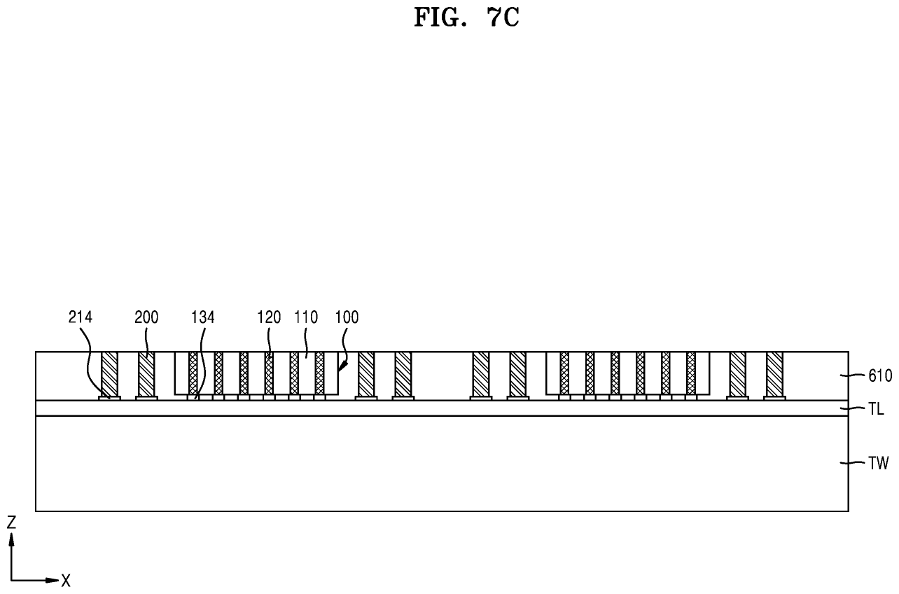

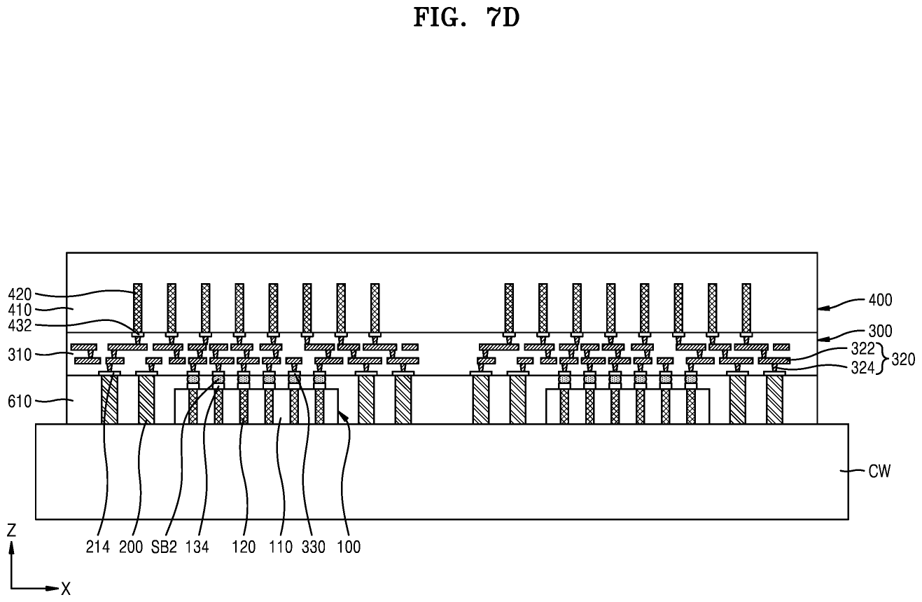

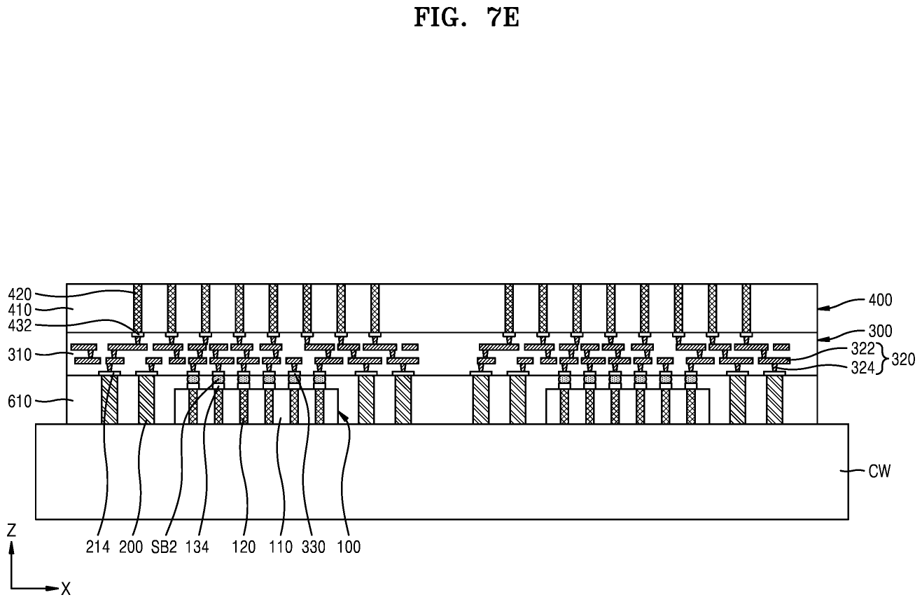

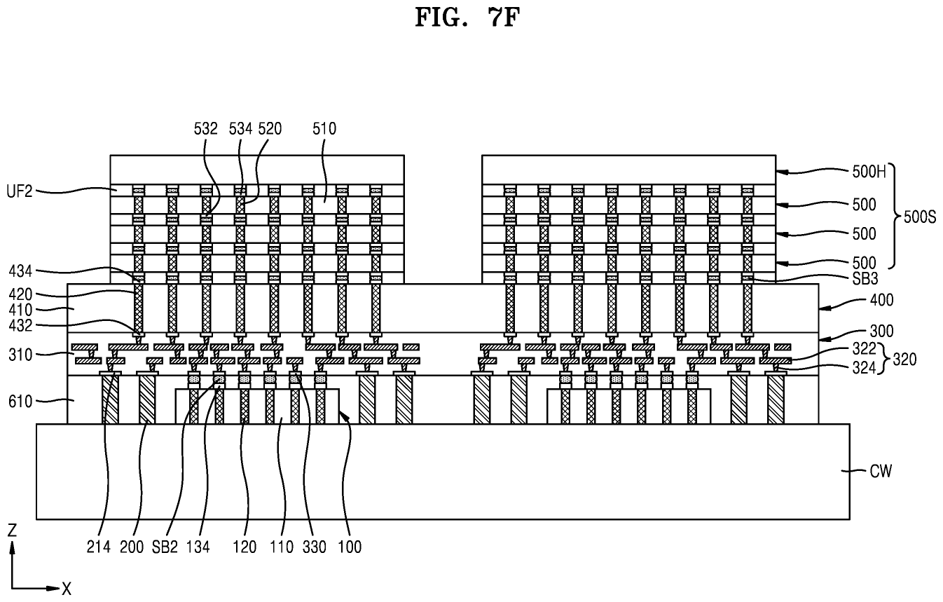

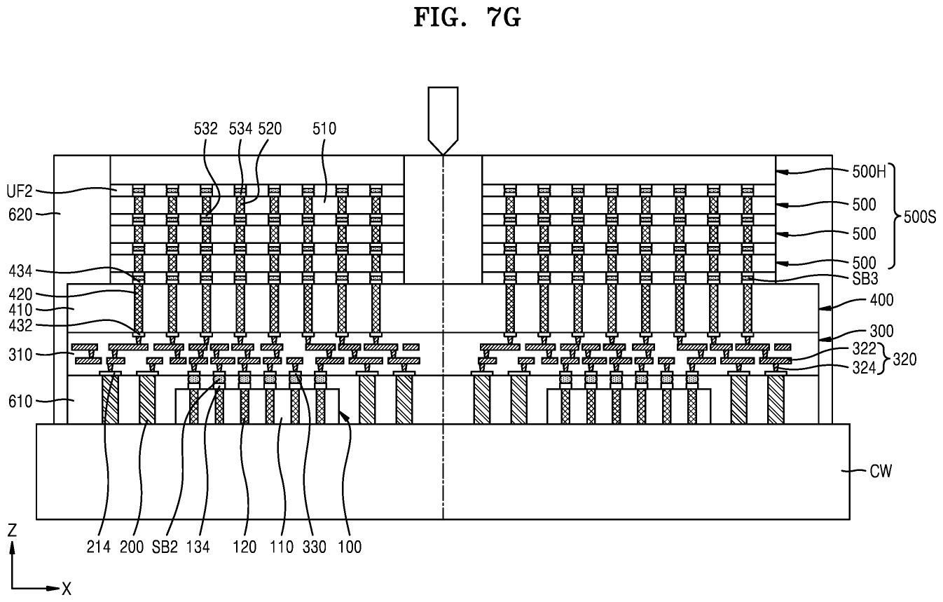

FIGS. 7A to 7G are cross-sectional views illustrating respective operations of a process of manufacturing the semiconductor device 1000, according to an embodiment of the inventive concept.

Referring to FIG. 7A, a tape substrate TW, to which an adhesive layer TL is attached, may be prepared, and a copper layer (not shown) may be attached on the adhesive layer TL. Thereafter, the post upper pad 214 and the conductive posts 200 may be sequentially formed using mask patterns (not shown). In an embodiment, the conductive posts 200 may be formed through an electroplating process using the copper layer as an electrode. Thereafter, the mask pattern may be removed, and as a result, the exposed copper layer may be etched. Accordingly, a portion of the adhesive layer TL may be exposed. In an embodiment, the etching process of the copper layer may be a wet etching process, but is not limited thereto.

Referring to FIG. 7B, the lower buffer chip 100 including the first upper pad 134 may be attached to the adhesive layer TL exposed in the result of FIG. 7A.

Referring to FIG. 7C, a first molding layer 610 covering the lower buffer chip 100 and the conductive posts 200 may be formed. After that, a grinding process of grinding a portion of the first molding layer 610 and a portion of the conductive posts 200 may be performed. The upper surface of the conductive posts 200 and the upper surface of the lower buffer chip 100 may be coplanar with one another by the grinding process.

Referring to FIG. 7D, a carrier substrate CW may be attached on the first molding layer 610. The carrier substrate CW may be formed of any one of a glass substrate, a silicon substrate, and a metal substrate. After that, the adhesive layer TL and the tape substrate TW may be removed to expose the post upper pad 214 and the first upper pad 134. After that, when the resultant product from which the adhesive layer TL and the tape substrate TW are removed is turned over, a first redistribution structure 300 may be formed on the post upper pad 214 and the first upper pad 134. The first redistribution structure 300 may be formed by repeatedly performing the processes of forming an insulating layer, patterning the insulating layer, and forming redistribution vias and redistribution line patterns on the patterned insulating layer. After that, the upper buffer chip 400 may be disposed on the first redistribution structure 300.

Referring to FIG. 7E, a grinding process of grinding a portion of the second semiconductor substrate 410 of the upper buffer chip 400 may be performed on the result of FIG. 7D. Through the grinding process, the upper surface of the second semiconductor substrate 410 and the upper surface of the second through electrode 420 may be coplanar with one another.

Referring to FIG. 7F, a second upper pad 434 may be formed in the result of FIG. 7E. The second upper pad 434 may be formed, for example, by using the mask pattern after forming a mask pattern (not shown). Thereafter, memory chip structures 500S including a plurality of memory chips 500 may be disposed on the upper buffer chip 400.

Referring to FIG. 7G, in the result of FIG. 7F, a second molding layer 620 surrounding the first molding layer 610, the first redistribution structure 300, the upper buffer chip 400, and the memory chip structures 500S may be formed. After that, the carrier substrate CW may be removed, and singulation may be performed. Thereafter, the post lower pad 212 (refer to FIG. 1) may be formed to form the semiconductor manufacturing apparatus 1000 illustrated in FIG. 1.

While the inventive concept has been particularly shown and described with reference to embodiments thereof, it will be understood that various changes in form and details may be made therein without departing from the spirit and scope of the following claims.

What is claimed is:

1. A semiconductor device comprising:
a first lower buffer chip;
an upper buffer chip disposed on an upper surface of the first lower buffer chip;
a plurality of conductive posts spaced apart from the first lower buffer chip and disposed on a lower surface of the upper buffer chip; and
a first memory chip stack structure disposed on the upper buffer chip and including a plurality of first memory chips.

2. The semiconductor device of claim 1, wherein a horizontal area of the upper buffer chip is different from a horizontal area of the first lower buffer chip.

3. The semiconductor device of claim 1, wherein a horizontal area of the upper buffer chip is greater than a horizontal area of the first lower buffer chip.

4. The semiconductor device of claim 1, wherein the first lower buffer chip comprises a first through electrode extending in a first direction perpendicular to the upper surface of the first lower buffer chip, and the upper buffer chip comprises a second through electrode extending in the first direction.

5. The semiconductor device of claim 4, wherein a width of the plurality of conductive posts is greater than a width of the first through electrode and a width of the second through electrode.

6. The semiconductor device of claim 1, wherein at least one of the first lower buffer chip and the upper buffer chip comprises an arithmetic circuit configured to calculate data stored in the plurality of first memory chips.

7. The semiconductor device of claim 1, further comprising:
a first molding layer surrounding the first lower buffer chip and the conductive posts; and
a second molding layer surrounding the first molding layer, the upper buffer chip, and the first memory chip stack structure.

8. The semiconductor device of claim 7, wherein the first molding layer and the second molding layer comprise different materials.

9. The semiconductor device of claim 1, further comprising a first redistribution structure disposed between the first lower buffer chip and the upper buffer chip.

10. The semiconductor device of claim 9, wherein the first redistribution structure is configured to be connected to the first lower buffer chip, the upper buffer chip, and the plurality of conductive posts.

11. The semiconductor device of claim 1, wherein the first lower buffer chip overlaps a center of the upper buffer chip in a first direction perpendicular to the upper surface of the first lower buffer chip.

12. The semiconductor device of claim 1, wherein the first lower buffer chip overlaps an edge portion of the upper buffer chip in a first direction perpendicular to the upper surface of the first lower buffer chip.

13. The semiconductor device of claim 1, further comprising a second redistribution structure disposed between the upper buffer chip and the first memory chip stack structure and configured to connect the upper buffer chip to the first memory chip stack structure.

14. The semiconductor device of claim 1, further comprising:
a second lower buffer chip disposed on a lower surface of the upper buffer chip and spaced apart from the first lower buffer chip; and
a second memory chip stack structure disposed on an upper surface of the upper buffer chip and including a plurality of second memory chips.

15. A semiconductor package comprising:
a redistribution structure;
a semiconductor device disposed on the redistribution structure; and
a semiconductor chip disposed on the redistribution structure and spaced apart from the semiconductor device in a horizontal direction,
wherein the semiconductor device comprises:
a lower buffer chip disposed on the redistribution structure;
an upper buffer chip disposed on an upper surface of the lower buffer chip;
a plurality of conductive posts spaced apart from the lower buffer chip and disposed on a lower surface of the upper buffer chip; and
a memory chip stack structure disposed on the upper buffer chip and including a plurality of memory chips.

16. The semiconductor package of claim 15, wherein at least one of the lower buffer chip and the upper buffer chip comprises arithmetic circuits configured to operate on data stored in the plurality of memory chips, wherein the plurality of memory chips comprise only memory cells.

17. The semiconductor package of claim 15, wherein the redistribution structure is configured to be connected to the lower buffer chip and the plurality of conductive posts.

18. The semiconductor package of claim 15, wherein the plurality of conductive posts are configured to apply power to the upper buffer chip and the memory chip stack structure.

19. A semiconductor device comprising:
a lower buffer chip including a first through electrode;
a plurality of conductive posts spaced apart from the lower buffer chip and disposed along a periphery of the lower buffer chip;
a first redistribution structure disposed on the lower buffer chip and the plurality of conductive posts;
an upper buffer chip disposed on the first redistribution structure and including a second through electrode; and
a memory chip stack structure disposed on the upper buffer chip and including a plurality of memory chips,
wherein a horizontal area of the upper buffer chip is greater than a horizontal area of the lower buffer chip and a vertical length of the upper buffer chip is greater than a vertical length of the lower buffer chip,
wherein a width of the plurality of conductive posts is greater than a width of the first through electrode and a width of the second through electrode.

20. The semiconductor device of claim 19, further comprising:
a first molding layer surrounding the lower buffer chip and the conductive posts; and
a second molding layer surrounding a portion of sidewalls of the first molding layer, a portion of sidewalls of the upper buffer chip, a portion of an upper surface of the upper buffer chip, and the memory chip stack structure,
wherein the first molding layer and the second molding layer comprise different materials.
